(19) United States
(12) Patent Application Publication
(10) Pub. No.: US 2010/0207890 A1
(43) Pub. Date: Aug. 19, 2010

(54) SINGAL DETECTING APPARATUS

(75) Inventor: Chang-Yi Chen, Bade City (TW)

Correspondence Address: ROGER H. CHU, 19499 ERIC DRIVE, SARATOGA, CA, 95070, US

(73) Assignee: IDEACOM TECHNOLOGY CORPORATION (TAIWAN), Shindian (TW)

(21) Appl. No.: 12/388,547

(22) Filed: Feb. 19, 2009

(51) Int. Cl. G06F 3/041; H03K 17/96

(52) U.S. Cl. 345/173; 327/517

(57) ABSTRACT

The invention relates to a signal detecting apparatus comprising at least one first transistor, a second transistor and at least one switch. At least one first transistor is used for generating at least one first adjusting current according to an input signal and a power provided by a voltage source. At least one switch coupled to the voltage source and at least one first transistor is used for controlling at least one first transistor to generate at least one first adjusting current according to at least one control signal. The second transistor coupled to at least one first transistor and a ground generates a second adjusting current according to the input signal. Wherein the signal detecting apparatus generates an output signal according to at least one first adjusting signal and the second adjusting signal.

### BACKGROUND OF THE INVENTION

1. Field of the Invention

The invention is related to a detecting apparatus, and more specifically related to a signal detecting apparatus for fast detecting whether a touch panel has been touched by user or not.

2. Description of the Prior Art

Various touch sensing technology are used in many different electronic products in recently years via it is growth better and more convenient for using. Touch pad is implement in various kinds of the electronic products because it has advantages of small size, cost less, low power assume and durable life.

Please referring to FIG. 1A, FIG. 1A is a schematic diagram of a conventional electronic system with 4-wires resistive touch panel. As shown in FIG. 1A, an electronic system 10 with a 4-wires resistive touch panel 12 includes the 4-wires resistive touch panel 12, a control module 14 and a back end processor 16, wherein the resistors R1, R2 are respecting to the equivalent resistors in the Y-axis direction and the resistors R3, R4 are respecting to the equivalent resistors in the X-axis direction. Four connecting lines of the 4-wires resistive touch panel 12 connecting to terminals X+, X−,Y+ and Y− of the control module 14 respectively to transmit data. If 4-wires resistor touch panel 12 is not been touched, the control module 14 connects the Y-terminal to ground AVSS by a switch 141 and connects the X+ terminal to a Pull-up resistor R5 and a buffer 143 to rectify signal and then output to processor 16 at the same time, the Y+ terminal is floating. The capacitors C1, C2, C3 and C4 are parasitic capacitors or additional capacitor for voltage stable. The additional capacitor which respecting to the parasitic capacitors of the terminals X+, X−, Y+ and Y− of the control module 14.

When the 4-wires resistive touch panel 12 has been touched, the separated X axis and the Y axis of the 4-wire resistive touch panel will connect to each other and the Y+ terminal and X− terminal are floating, currents flow in the path between the resistors R2, R3 and R5. After executing the voltage division operation with the resistance of the R2, R3 and R5, the X− terminal generates a low voltage level signal, the buffer 143 transforms the low voltage level signal from analog format to digital format and then outputs to the back end processor 16 to trigger processor 16 to prepare processing the data transmitted by the 4-wires resistor touch panel further detecting the position or the trace information that pressed on the touch panel 12.

When the 4-wires resistive touch panel 12 is released from the pressed operation by the user, the equivalent resistors R1, R2, R3 and R4 of touch panel 12 are open, the X+ terminal generates a high voltage signal, the buffer 143 transforms the high voltage level signal from analog format to digital format to trigger the processor 16 to detect the operation of the 4-wires resistive touch panel 12 again.

Please referring to the FIGS. 1A to 1C, FIG. 1B is a signal waveform diagram for determining a 4-wires resistive touch panel has been touched or not. FIG. 1C is a signal waveform diagram for determining the 4-wires resistive touch panel from touched to released. As shown in the FIGS. 1A to 1C, an inverter is used for the buffer 143 in general, the threshold voltage is about half of the amplitude between the two voltage source AVDD and AVSS for transition. If the buffer 143 implement in the control module 14 described above, the capacitance of the capacitors C1, C2, C3 and C4 are too large to cause the problem that the charging or discharging of X+ terminal too slow that the signal of the X+ terminal can't process by the processor 143 in time. Wherein the signal as shown as the FIG. 1B is the receiving signal received at the X+ terminal from touch panel 12 which generated due to pressing the touch panel 12 by the user. At this time, the electronic system 10 determines whether the touch panel 12 has been pressed or not by detecting the signal reaches the threshold voltage VTH1 correspondingly. In the contrast, the signal as shown as in FIG. 1C is the signal generated by the touch panel 12 released from pressed. The electronic system 10 determines whether the touch panel 12 release or not by detecting the signal reaches the threshold voltage VTH1 correspondingly. It exists a delay period between the actual operation by the user and the control module 14 determines the touch panel 12 is pressed or released, as shown as the Delay time 1 and Delay time 2 in FIGS. 1B and 1C, which affects the electronic system 10 can't determines the operation of the 4-wires resistive touch panel 12 in time and causes the problems that the sensitivity of the touch panel 12 is bad or the sample data is incorrect.

As mentioned above, how to provide user a signal detecting apparatus which can fast detect whether the touch panel be operated or not and reduce the responding time of detecting touch operation of the electronic system with the touch panel is became an important topic of technology of the electronic system which including the touch panel.

### SUMMARY OF THE INVENTION

It is therefore a primary objective of the present invention to provide a signal detecting apparatus for adjusting the threshold voltage used to determine whether the touch panel be touched or not, and then determines whether the touch panel be pressed or released according to the adjusted threshold voltage to fast detect the operation condition of the touch panel.

One embodiment of the present invention provides a signal detecting apparatus comprising at least one first transistor, a second transistor and at least one switch. At least one first transistor is used for generating at least one first adjusting current according to an input signal and a power provided by a voltage source. At least one switch coupled to the voltage source and at least one first transistor is used for controlling at least one first transistor to generate at least one first adjusting current according to at least one control signal. The second transistor coupled to at least one first transistor and a ground generates a second adjusting current according to the input signal. Wherein the signal detecting apparatus generates an output signal according to at least one first adjusting signal and the second adjusting signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a schematic diagram of a conventional electronic system with 4-wires resistive touch panel.

FIG. 1B is a signal waveform diagram for determining a 4-wires resistive touch panel has been touched or not.

FIG. 1C is a signal waveform diagram for determining the 4-wires resistive touch panel from touched to released.

FIG. 2 is a schematic diagram of an embodiment of the signal detecting apparatus according to the present invention.

FIG. 3A is a signal waveform diagram for detecting the touched condition of the signal detecting apparatus of the present invention.

FIG. 3B is a signal waveform diagram for detecting the touch panel from touched to released of the signal detecting apparatus of the present invention.

FIG. 4 is a signal waveform diagram of the signal detecting apparatus of the present invention.

### DETAILED DESCRIPTION

Please referring to FIG. 2, FIG. 2 is schematic diagram of an embodiment of the signal detecting apparatus according to the present invention. As shown in FIG. 2, the present invention is a signal detecting apparatus 20 comprising a control unit (not shown), an input terminal T_{IN}, at least one first transistor 22, at least switch 26, a second transistor 24 and an output terminal T_{OUT}. The control unit (not shown) is used for generating at least one control signal S_{C1}˜S_{C3}. The input terminal TIN is used for receiving input terminal SIN. In one of the embodiment, the signal detecting apparatus 20 is suited in an electronic system with a touch panel; the input signal SIN is an output signal which generated by pressing the touch panel or from pressing to release the touch panel. At least one first transistor 22 coupled to the input terminal T_{IN} is used for generating at least one first adjusting current 111˜113 according to a power V_{P} generated by a voltage source AVDD and the input signal S_{IN}. At least one switch 26 coupled between the voltage AVDD and at least one first transistor 22 is used for turning on or off according to at least one control signal S_{C1}˜S_{C3} and controlling at least one first transistor 22 generating at least one first adjusting current I₁₁˜I₁₃. The second transistor 24 coupled to at least one first transistor 22, the input terminal T_{IN} and a ground AVSS is used for generating a second adjusting signal I₂ according to the input signal S_{IN}. The output terminal T_{OUT} coupled to at least one first transistor 22 and the second transistor 24 is used for generating a output signal S_{OUT} according to at least one first adjusting current I₁₁˜I₁₃ and the second adjust current I₂.

In one embodiment, at least one first transistor 22 is a P-MOSFET (P-Channel Metal-Oxide-Semiconductor Field-Effect Transistor). Please referring FIG. 2, taking at least one first transistor 22 includes three first transistors MO1, MO2 and MO3 for example, each one of the first transistors MO1, MO2 and MO3 includes a first first terminal T₁₁₁˜T₁₁₃ (source), a first control terminal T_{C11}˜T_{C13} (gate) and a first second terminal T₁₂₁˜T₁₂₃ (drain). The first first terminal T₁₁₁˜T₁₁₃ coupled to one terminal of the at least one switch 26 is used for receiving the power VP. The first control terminal T_{C11}˜T_{C13} coupled to the input terminal T_{IN} is used for generating at least one first adjusting current I₁₁˜I₁₃ according to the input signal S_{IN} and the power VP. It must be notices that each one of P-MOSFETs MO1, MO2 and MO3 has different size. As the control of those switches 26, further controlling the different current flow into those first transistors MO1, MO2 and MO3 respectively to generate different fist adjusting current I₁₁˜I₁₃.

The second transistor 24 is an N-MOSFET (N-Channel Metal-Oxide-Semiconductor Field-Effect Transistor) which including a second first terminal T₂₁ (source), a second control terminal T_{C2} (gate) and a second second terminal T₂₂ (drain). The second first terminal coupled to the ground AVSS, the second control terminal T_{C2} coupled to the input terminal T_{IN} is used for receiving the input signal S_{IN} and the second second terminal T₂₂ coupled to the output terminal T_{OUT} is used for generating the second adjusting current according to the input signal S_{IN}.

The number of the at least one switch 26 is corresponding to the number of at least one first transistor 22, in this embodiment, there are three switches MB1, MB2 and MB3 which are an MOS switch respectively. Each one switch MB1˜MB3 of at least one switch 26 includes first terminal T_{S11}˜T_{S13}, a control terminal T_{CS1}˜T_{CS3} and a second terminal T_{S21}˜T_{S23}. The first terminal TS11˜TS13 coupled to the voltage source AVDD are used for receiving the voltage source VP. The control terminal TCS1˜TCS3 coupled to the control unit (not shown) are used for receiving at least one control signal SC1, SC2 and SC3 and turning on or off according to at least one control SC1,SC2 and SC3 correspondingly. The second terminal TS21, TS22 and TS23 coupled to at least one first transistor MO1, MO2 and MO3 are used for transmitting the power VP to at least one first transistor MO1, MO2 and MO3 when the control terminal TCS1˜TCS3 are turned on. In must be noticed that the number of at least one first transistor 22, the number of at least one switch 26 and the size of the at least one first transistor 22 can be determined by the user according to the actual condition. The embodiments described above are used for explaining the operation of the signal detecting apparatus but not limited to the present invention.

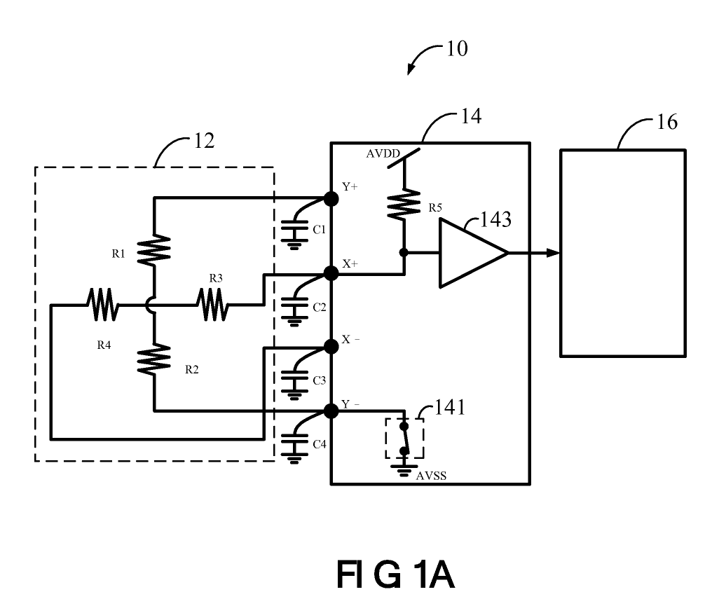

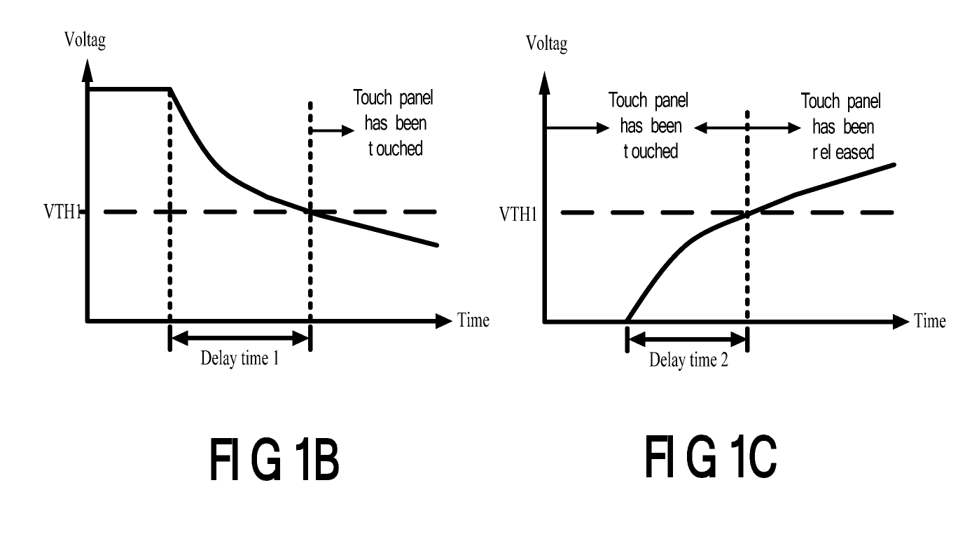

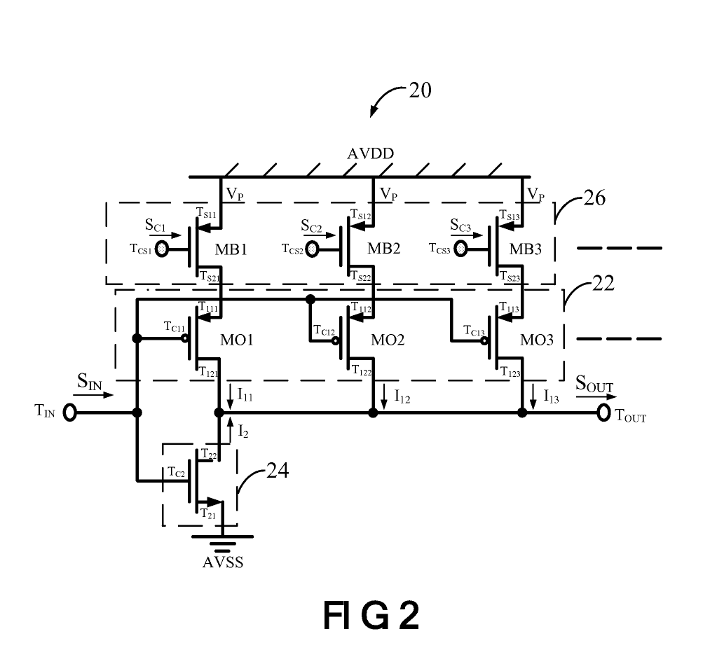

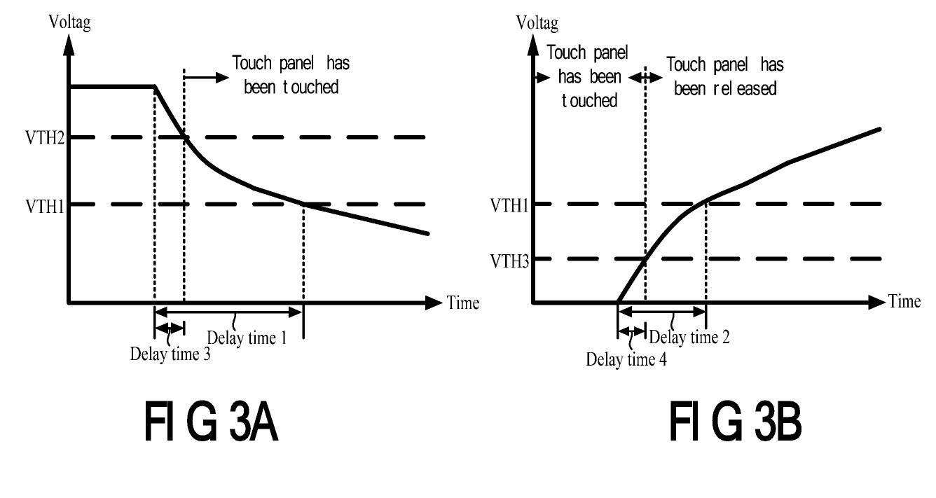

Please referring to FIGS. 2, 3A, 3B and the architecture of the electronic system in FIG. 1A. FIG. 3A is a signal waveform diagram for detecting the touched condition of the signal detecting apparatus of the present invention. FIG. 3B is a signal waveform diagram for detecting the touch panel from touched to released of the signal detecting apparatus of the present invention. The signal detecting apparatus 20 of present invention controls at least one switch 26 (MB1˜MB3) by the control signals SC1, SC2 and SC3 to switch the P-MOSFET MO1, MO2 and MO3 with different size respectively for controlling the level of the threshold voltage VTH1 and further adjusting the threshold voltage VTH1 to the threshold Voltage VTH3 and VTH2. Therefore, when the touch panel is pressed, after the operation with the equivalent resistances of the resistors (R2, R3 and R5), the X+ terminal generates a low voltage level signal to discharge slowly because the capacitances of the capacitors (C1, C2, C3 and C4) are too large. The signal detecting apparatus 20 automatically adjusts the threshold voltage VTH1 to VTH2 for shortening the responding time effectively. If the delay time (Delay time 3) during the input signal SIN reach the threshold voltage VTH2 is more less than the delay time (Delay time 1) during the input signal SIN reaches the threshold voltage VTH1, it can fast transform the analog signal at the X+ terminal to the low level digital logic signal and outputs it the processor 16 to prepare operating and processing the data of the touch panel 12. Furthermore, user can predetermined setting various threshold voltages and then chooses one set of the threshold voltage to be the criterion for detecting the pressing action or the releasing action executed to the touch panel 12 by the user according to the actual situation.

Please referring to FIG. 3B, at the same way, when the touch panel has been released from pressed, the capacitors C1˜C4 cause the X+ terminal generate a high voltage signal to charge slowly. It can shorten the original delay time from Delay time 2 to Delay time 4 by adjusting the threshold voltage from VTH1 to VTH3. Adjusting the threshold voltage VTH2 and VTH3 is executed by control those first adjusting current I11˜I13. As those embodiments, the signal adjusting apparatus 20 can fast detect the input signal SIN and determines the touch panel been pressed or been released from pressed.

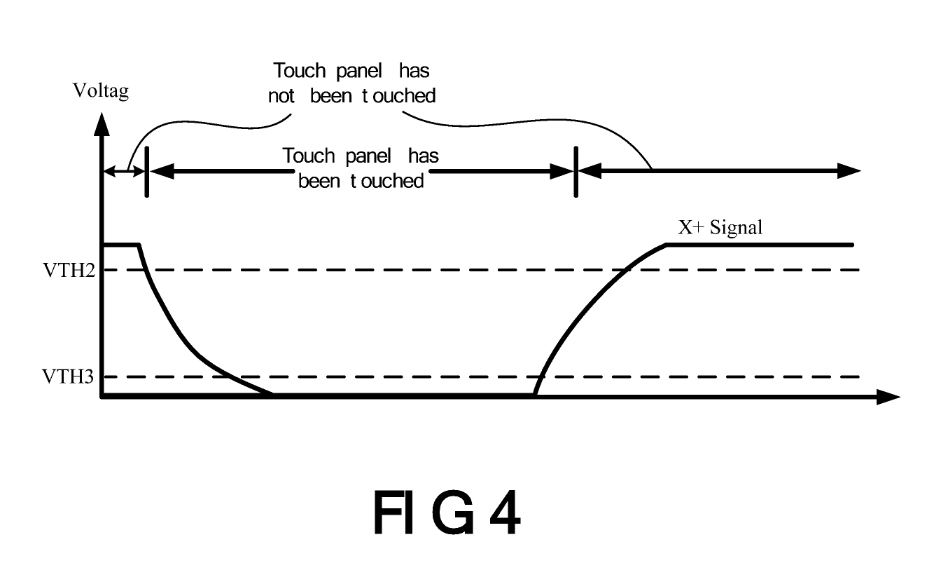

Please referring to FIGS. 1A and 4, FIG. 4 is a signal waveform diagram of the signal detecting apparatus of the present invention. This embodiment is used for explaining the operation of the buffer 143 of the signal detecting apparatus in the electronic system 10 with the touch panel 12. At first, the buffer 143 predetermined sets the high voltage level as the threshold voltage VTH2 according to the actual condition to enhance the ability for detecting the pressing operation executed to the touch panel 12 which can improve the respond of the electronic system to enhance the detecting ability of the electronic system 10 for detecting the pressing operation executed by the user on the touch panel.

When it is determined the touch panel has been pressed, the electronic system 10 samples and operates voltage division N times and sample and divided the voltage of the Y axis M times to complete the processing of a coordinate location. If the touch panel still has been pressed in this time, the electronic system 10 continued samples and operates voltage division of the X axis of the touch panel N time and processing next data. After completing one or more coordinate position processing, the threshold voltage VTH3 of the buffer 143 is reset to a low voltage level to make sure the potential of the X+ terminal discharging and the voltage level lower than the threshold voltage to prevent the electronic system 10 from error operation and prepare to detect whether the touch panel 12 been released from pressed.

When the electronic system 10 outputs the power command, the control module 14 switches the detecting mode of the touch panel to make the X+ terminal generating a high voltage level signal to charge slowly. The buffer 143 with the adjusted threshold voltage VTH3 can fast respond and transmit the signal to the back end processor 16 to stop processor 16 remained executing sample and operate with the data of the touch panel 12, for improving the problem of data transmitting error that generating the hops.

When completing one or more data sampling and processing, the potential of the X+ terminal has been charged and the voltage level is higher than threshold voltage VTH2, the threshold voltage VTH2 of the buffer 143 is reset to a high voltage level to make sure the electronic system 10 will not operating error and further prepare to detect the condition of the touch panel 12 next time.

The following description is used for explaining the operation of the buffer 143, in one embodiment at least one first adjusting current I₁₁˜I₁₃ are a charging current respectively and the second adjusting current I2 is a discharging current. When the level of input signal less than the threshold voltage VTH2, those charging current is large than the discharging current to generate the output signal S_{OUT} with high voltage level. In contrast, when the level of the input signal S_{IN} large than the threshold voltage VTH3, the discharging current is large than those charging current to generate the output signal S_{OUT} with low voltage level∘ The description above is the operation theory of the buffer 143 using as an inverter. The processor 16 determines the operation condition of the touch panel according to the level of the output signal S_{OUT}.

The embodiments described above are taking the signal detecting apparatus 20 implement in an electronic system which includes a 4-wires resistive touch panel for example, but it is not limited to present invention. The signal detecting apparatus 20 of the present invention also can use to detect whether a 5-wires resistive touch panel been pressed or not, the difference between those two embodiments is that connecting the signal detecting apparatus 20 to a Wiper terminal of the 5-wires resistive touch panel instead of connecting it to the X+ terminal to the 4-wires resistive touch panel.

The levels of the threshold voltages VTH2 and VTH3 can be adjusted by the user according to the actual condition, it has been noticed that the levels of the threshold voltage VTH2 and VTH3 must cover the error or noise of the input signal SIN to prevent the signal detecting signal 20 generating the error and further generating the problem.

As mentioned above, the present invention provides a signal detecting apparatus for adjusting the detecting standard criteria to automatically adjust the threshold voltage of the buffer of the touch panel. The signal detecting apparatus can fast determine the operation condition of the touch panel to shorten the processing time and further enhance the efficiency for operating touch panel.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal detecting apparatus, comprising:
a control unit for generating at least one control signal;
an input terminal for receiving an input signal;
at least one first transistor coupled to the input terminal for generating at least one first adjusting current according to the input signal and a power generated by a voltage source;
at least one switch coupled between the voltage source and at least one first transistor for turning on or off according to at least one control signal to control at least one first transistor generating at least one first adjusting current;
a second transistor coupled to at least one first transistor, the input terminal and a ground for generating a second adjusting current according to the input signal; and
an output terminal coupled to at least one first transistor and the second transistor for generating an output signal according to at least one first adjusting current and the second adjusting current.

2. The signal detecting apparatus of claim 1, wherein at least one first transistor is a P-MOSFET (P-Channel Metal-Oxide-Semiconductor Field-Effect Transistor) and the second transistor is an N-MOSFET (N-Channel Metal-Oxide-Semiconductor Field-Effect Transistor).

3. The signal detecting apparatus of claim 2, wherein each of the at least one P-MOSFET has different size.

4. The signal detecting apparatus of claim 1, wherein each of at least one first transistor includes:
a first first terminal coupled to one terminal of at least one switch for receiving the power;
a first control terminal coupled to the input terminal for receiving the input signal; and
a first second terminal coupled to the output terminal for generating at least one first adjusting current according to the input signal and the power.

5. The signal detecting apparatus of claim 4, wherein at least one first transistor is a P-MOSFET (P-Channel Metal-Oxide-Semiconductor Field-Effect Transistor), the first first terminal is a source, the first control terminal is a gate and the first second terminal is a drain.

6. The signal detecting apparatus of claim 1, wherein the second transistor includes:
a second first terminal coupled to the ground;
a second control terminal coupled to the input terminal for receiving the input signal; and
a second second terminal coupled to the output terminal for generating the second adjusting current according to the input signal.

7. The signal detecting apparatus of claim 6, wherein the second transistor is an N-MOSFET (N-Channel Metal-Oxide-Semiconductor Field-Effect Transistor), and the second first terminal is a source, a second control terminal a gate and a second second terminal is a drain.

8. The signal detecting apparatus of claim 1, wherein at least one switch a MOS switch.

9. The signal detecting apparatus of claim 1, wherein each of at least one switches includes:
a first terminal coupled to the voltage source for receiving the power;
a control terminal coupled to the control unit for receiving at least one control signal and selectively turning on or off corresponding to at least one control signal; and
a second terminal coupled to at least one first transistor for transmitting the power to at least one first transistor.

10. The signal detecting apparatus of claim 1, wherein at least one first adjusting current is a charging current and the second adjusting current is a discharging current.

11. The signal detecting apparatus of claim 1, wherein the signal detecting apparatus is suited in an electronic system with a touch panel.

12. The signal detecting apparatus of claim 2, wherein the input signal is an output signal generated by the pressing the touch panel.
